(19) United States
(12) Patent Application Publication
(10) Pub. No.: US 2025/0147112 A1
(43) Pub. Date: May 8, 2025

(54) Secondary Battery State of Health Estimation Method, Secondary Battery State of Health Estimation Program, and Secondary Battery State of Health Estimation Apparatus

(71) Applicant: ELIIY Power Co., Ltd., Tokyo (JP)

(72) Inventors: Takahiro MIYAZAKI, Tokyo (JP); Hideyuki SUGIYAMA, Tokyo (JP)

(73) Assignee: ELIIY Power Co., Ltd., Tokyo (JP)

(21) Appl. No.: 18/684,569

(22) PCT Filed: Aug. 19, 2022
(86) PCT No.: PCT/JP2022/031361

§ 371 Date: Feb. 16, 2024

(30) Foreign Application Priority Data
Aug. 19, 2021 (JP) 2021-134409

(51) Int. Cl. G01R 31/392; G01R 31/36; G01R 31/367; H02J 7/00

(52) U.S. Cl. CPC G01R 31/392; G01R 31/3648; G01R 31/367; H02J 7/005; H02J 2300/24

(57) ABSTRACT

In a secondary battery state of health (SOH) estimation method, which estimates the state of health (SOH) of a secondary battery by use of a Weibull law, Weibull coefficients m_{f}, η_{f} corresponding to a float capacity retention rate, and the float capacity retention rate represented by the following formula (1) are obtained from the measurement values of a float test for determining the capacity retention rate; Weibull coefficients m_{c}, η_{c} corresponding to a cycle capacity retention rate, and the cycle capacity retention rate represented by the following formula (2) are obtained from the measurement values of a cycle test for determining the capacity retention rate; and the capacity retention rate in a period t or at a cycle number N is estimated from the float capacity retention rate and the cycle capacity retention rate of the secondary battery.

$$\begin{matrix}[ Equation 1 ] & \\ Float capacity retention rate = exp \{ - {( \frac{t}{{η}_{f}} )}^{{m}_{f}} \} & ( 1 )\end{matrix}$$

$$Cycle capacity retention rate = exp \{ - {( \frac{N}{{η}_{c}} )}^{{m}_{c}} \} \qquad ( 2 )$$

### TECHNICAL FIELD

This invention relates to a secondary battery State of Health (SOH) estimation method, a secondary battery state of health estimation program, and a secondary battery state of health estimation apparatus in a storage battery system which has a storage battery composed of a rechargeable and dischargeable secondary battery cell as a single unit, or a plurality of rechargeable and dischargeable secondary battery cells connected in series or parallel, and which also has a power regulator connected to the storage battery, a commercial power source, and a power generator and capable of supplying electric power (or power) to a load to be connected.

### BACKGROUND ART

A proposal has been made for a storage battery system which accumulates power, generated using natural energy such as sunlight, in a storage battery in order to curb the use of a commercial power source, and supplies the power accumulated in the storage battery, instead of the commercial power source, to a load requiring power.

A storage battery system described as above, for example, is often used in one or two charge/discharge cycles/day, and the state of health of its secondary battery is known to decline gradually owing to cycle deterioration or aged deterioration. The capacity of the secondary battery after long-term use cannot be known unless it is actually measured. A gradual decrease in the state of health of the secondary battery, however, leads to the stoppage of the storage battery system used. To grasp the present situation of the secondary battery in operation, therefore, it is becoming necessary to predict the state of health of the secondary battery. To satisfy a requirement for reduction of environmental burden, moreover, a demand is also being voiced for extension of the usage period of the storage battery system. Thus, it is becoming necessary to predict the life of the secondary battery in the future.

Conventional methods known are one which prepares many maps showing a complicated charging state to correct the state of health, and a formula for prediction of the state of health. As the formula for prediction of the state of health, one using a root law or a power law is known. It is known that the capacity reduction rate of a secondary battery is determined according to a one-half power law (root law) which defines that the capacity reduction rate of the secondary battery is proportional to the one-half power of the flowing current amount (current integrated value) of the secondary battery, or is proportional to the one-half power of the standing time of the secondary battery. The relevant formula is as indicated below. If the square root of the flowing current amount which is the flowing current (current amount) of the secondary battery integrated over time is determined, the deterioration state (or capacity reduction rate) of the secondary batter can be estimated.

$$Capacity deterioration rate = k \sqrt{t} = {kt}^{0.5} \qquad [ Equation 1 ]$$

$$State of health = 1 \cdot k \sqrt{t} = 1 \cdot {kt}^{0.5}$$

Furthermore, there is disclosed a technology which obtains an integrated charge amount based on the charge/discharge current over time, without interrupting power supply from a secondary battery and without discharging the secondary battery up to a discharge stoppage state, thereby making it possible to estimate the full charge capacity or remaining capacity of the secondary battery (see, for example, Patent Document 1). Relevant formulas are as follows (power law):

$$Capacity deterioration rate = {kt}^{n} \qquad [ Equation 2 ]$$

$$State of health = 1 - {kt}^{n}$$

However, the root law poses the problem that the values obtained thereby deviate greatly from actual measurements. On the other hand, the power law shows a good fitting, but similarly causes a deviation from the actual value. Besides, both the root law and the power law mathematically give values which can be less than a state of health of 0%. Thus, the problem arises that predicted values in long-term prediction are below measured values.

The inventors, therefore, proposed a novel state of health estimation method using the Weibull law (see Non-Patent Document 1). Such a method grasps a battery as an assembly of partial batteries, and enables life to be estimated by prediction of its failure rate. This method is represented by the following formulas:

$$Capacity deterioration rate = 1 - exp \{ - {( \frac{t}{η} )}^{m} \} \qquad [ Equation 3 ]$$

$$State of health = exp \{ - {( \frac{t}{η} )}^{m} \}$$

### PRIOR ART DOCUMENTS

### Patent Documents

[Patent Document 1] JP-A-2009-52974

### Non-Patent Documents

[Non-Patent Document 1] Abstracts of Presentations, The 59th Battery Symposium in Japan, P212, published on Nov. 26, 2018

### SUMMARY OF THE INVENTION

### Problems to be Solved by the Invention

The above state of health estimation method using the Weibull law provides results coincident satisfactorily with measured values in comparison with the root law or the power law, but brings about great errors in connection with long-term prediction. Its practical utilization, therefore, requires more accurate life prediction.

The present invention has been accomplished in the light of the above-mentioned circumstances. It is an object of this invention to provide a secondary battery state of health estimation method, a secondary battery state of health estimation program, and a secondary battery state of health estimation apparatus which estimate the state of health (SOH) of a secondary battery accurately for a longer period of time.

### Means for Solving the Problems

A first aspect of the present invention, designed to solve the above-mentioned problems, resides in a secondary battery State of Health (SOH) estimation method, which estimates the State of Health (SOH) of a secondary battery by use of a Weibull law, comprising:
obtaining Weibull coefficients m_{f}, η_{f} corresponding to a float capacity retention rate, and the float capacity retention rate represented by the following formula (1), from measurement values of a float test for determining the state of health;
obtaining Weibull coefficients m_{c}, η_{c} corresponding to a cycle capacity retention rate, and the cycle capacity retention rate represented by the following formula (2), from measurement values of a cycle test for determining the state of health; and
estimating the state of health in a period t or at a cycle number N from the float capacity retention rate and the cycle capacity retention rate of the secondary battery.

$$\begin{matrix}[ Equation 4 ] & \\ Float capacity retention rate = exp \{ - {( \frac{t}{{η}_{f}} )}^{{m}_{f}} \} & ( 1 )\end{matrix}$$

$$Cycle capacity retention rate = exp \{ - {( \frac{N}{{η}_{c}} )}^{{m}_{c}} \} \qquad ( 2 )$$

A second aspect of the present invention resides in the secondary battery state of health estimation method according to the first aspect, comprising:

taking the capacity retention rate obtained from the float test as a measured float capacity retention rate, and Weibull plotting the measured float capacity retention rate in relation to In(period) and In(In(1/capacity retention rate)) to prepare a Weibull plot of the float capacity retention rate;
estimating a float deterioration prediction line, represented by a straight-line equation, from the Weibull plot of the float capacity retention rate;
obtaining the Weibull coefficients me and ne from a slope and an intercept of the float deterioration prediction line;
determining the float capacity retention rate from the Weibull coefficients m_{f} and η_{f} and the formula (1);
taking the capacity retention rate obtained from the cycle test as a measured cycle capacity retention rate, and Weibull plotting the measured cycle capacity retention rate in relation to In(cycle number) and In(In(1/capacity retention rate)) to prepare a Weibull plot of the cycle capacity retention rate;
estimating a cycle deterioration prediction line, represented by a straight-line equation, from the Weibull plot of the cycle capacity retention rate;
obtaining the Weibull coefficients m_{c} and nc from a slope and an intercept of the cycle deterioration prediction line; and
determining the cycle capacity retention rate from the Weibull coefficients m_{c} and η_{c} and the formula (2).

A third aspect of the present invention resides in the secondary battery state of health estimation method according to the first or second aspect, comprising:
determining the state of health from four arithmetic operations on the float capacity retention rate and the cycle capacity retention rate.

A fourth aspect of the present invention resides in the secondary battery state of health estimation method according to any one of the first to third aspects, comprising:
estimating the state of health as the state of health in the period t or at the cycle number N from the following formula (A):

$$\begin{matrix}[ Equation 5 ] & \\ State Of Health ( S O H ) = exp \{ - {( \frac{t}{{η}_{f}} )}^{{m}_{f}} \} \times exp \{ - {( \frac{N}{{η}_{c}} )}^{{m}_{c}} \} & ( A )\end{matrix}$$

A fifth aspect of the present invention resides in the secondary battery state of health estimation method according to any one of the first to third aspects, comprising:
estimating the state of health as the state of health in the period t or at the cycle number N from the following formula (B):

$$\begin{matrix}[ Equation 6 ] & \\ State Of Health ( S O H ) = exp \{ - {( \frac{t}{{η}_{f}} )}^{{m}_{f}} \} + exp \{ - {( \frac{N}{{η}_{c}} )}^{{m}_{c}} \} & ( B )\end{matrix}$$

A sixth aspect of the present invention resides in a secondary battery state of health estimation program, which estimates the state of health (SOH) of a secondary battery by use of a Weibull law, the program comprising making a computer work to perform:
a step of obtaining Weibull coefficients m_{f}, η_{f} corresponding to a float capacity retention rate, and the float capacity retention rate represented by the following formula (1), from measurement values of a float test for determining the capacity retention rate;
a step of obtaining Weibull coefficients m_{c}, η_{c} corresponding to a cycle capacity retention rate, and the cycle capacity retention rate represented by the following formula (2), from measurement values of a cycle test for determining the capacity retention rate; and
a step of estimating the state of health in a period t or at a cycle number N from the float capacity retention rate and the cycle capacity retention rate of the secondary battery.

$$\begin{matrix}[ Equation 7 ] & \\ Float capacity retention rate = exp \{ - {( \frac{t}{{η}_{f}} )}^{{m}_{f}} \} & ( 1 )\end{matrix}$$

$$Cycle capacity retention rate = exp \{ - {( \frac{N}{{η}_{c}} )}^{{m}_{c}} \} \qquad ( 2 )$$

A seventh aspect of the present invention resides in the secondary battery state of health estimation program according to the sixth aspect, the program comprising making a computer work to perform:
a step of taking the capacity retention rate obtained from the float test as a measured float capacity retention rate, and Weibull plotting the float component capacity retention rate in relation to In(period) and In(In(1/capacity retention rate)) to prepare a Weibull plot of the float capacity retention rate;
a step of estimating a float deterioration prediction line, represented by a straight-line equation, from the Weibull plot of the float capacity retention rate;
a step of obtaining the Weibull coefficients me and ne from a slope and an intercept of the float deterioration prediction line;
a step of determining the cycle capacity retention rate from the Weibull coefficients m_{f} and η_{f} and the formula (1);
a step of taking the capacity retention rate obtained from the cycle test as a measured cycle capacity retention rate, and Weibull plotting the cycle capacity retention rate in relation to In(cycle number) and In(In(1/capacity retention rate)) to prepare a Weibull plot of the cycle capacity retention rate;
a step of estimating a cycle deterioration prediction line, represented by a straight-line equation, from the Weibull plot of the cycle capacity retention rate;
a step of obtaining the Weibull coefficients me and ne from a slope and an intercept of the cycle deterioration prediction line; and
a step of determining the cycle capacity retention rate from the Weibull coefficients me and ne and the formula (2).

An eighth aspect of the present invention resides in the secondary battery state of health estimation program according to the sixth or seventh aspect,
the program comprising making a computer work to perform:
a step of determining the state of health from four arithmetic operations on the float capacity retention rate and the cycle capacity retention rate.

A ninth aspect of the present invention resides in the secondary battery state of health estimation program according to any one of the sixth to eighth aspects,
the program comprising making a computer work to perform:
a step of estimating the state of health as the state of health in the period t or at the cycle number N from the following formula (A):

$$\begin{matrix}[ Equation 8 ] & \\ State Of Health ( S O H ) = exp \{ - {( \frac{t}{{η}_{f}} )}^{{m}_{f}} \} \times exp \{ - {( \frac{N}{{η}_{c}} )}^{{m}_{c}} \} & ( A )\end{matrix}$$

A tenth aspect of the present invention resides in the secondary battery state of health estimation program according to any one of the sixth to eighth aspects,
the program comprising making a computer work to perform:
a step of estimating the state of health as the state of health in the period t or at the cycle number N from the following formula (B):

$$[ Equation 9 ]$$

$$State Of Health ( SOH ) = exp \{ - {( \frac{t}{{η}_{f}} )}^{{m}_{f}} \} + exp \{ - {( \frac{N}{{η}_{c}} )}^{{m}_{c}} \} \qquad ( B )$$

An eleventh aspect of the present invention resides in a secondary battery state of health estimation apparatus, which performs a secondary battery state of health estimation method to estimate a state of health (SOH) of a secondary battery,
the apparatus comprising:
storage means storing data on a cycle test and a float test; and
data acquisition means for acquiring data on the secondary battery in operation, a period t, and a cycle number N from the secondary battery;
the apparatus executing
a step of obtaining Weibull coefficients m_{f}, η_{f} corresponding to a float capacity retention rate, and the float capacity retention rate represented by the following formula (1), from measurement values of the float test;
a step of obtaining Weibull coefficients me, ne corresponding to a cycle capacity retention rate, and the cycle capacity retention rate represented by the following formula (2), from measurement values of the cycle test; and
a step of estimating the state of health in the period t or at the cycle number N from the float capacity retention rate and the cycle capacity retention rate of the secondary battery.

$$[ Equation 10 ]$$

$$Float capacity retetion rate = exp \{ - {( \frac{t}{{η}_{f}} )}^{{m}_{f}} \} \qquad ( 1 )$$

$$Cycle capacity retention rate = exp \{ - {( \frac{N}{{η}_{c}} )}^{{m}_{c}} \} \qquad ( 2 )$$

A twelfth aspect of the present invention resides in the secondary battery state of health estimation apparatus according to the eleventh aspect,
the apparatus executing
a step of taking the capacity retention rate obtained from the float test as a measured float capacity retention rate, and Weibull plotting the float component capacity retention rate in relation to In(period) and In(In(1/capacity retention rate)) to prepare a Weibull plot of the float capacity retention rate;
a step of estimating a float deterioration prediction line, represented by a straight-line equation, from the Weibull plot of the float capacity retention rate;
a step of obtaining the Weibull coefficients m_{f} and η_{f} from a slope and an intercept of the float deterioration prediction line;
a step of determining the cycle capacity retention rate from the Weibull coefficients m_{f} and η_{f} and the formula (1);
a step of taking the capacity retention rate obtained from the cycle test as a measured cycle capacity retention rate, and Weibull plotting the cycle capacity retention rate in relation to In(cycle number) and In(In(1/capacity retention rate)) to prepare a Weibull plot of the cycle capacity retention rate;
a step of estimating a cycle deterioration prediction line, represented by a straight-line equation, from the Weibull plot of the cycle capacity retention rate;
a step of obtaining the Weibull coefficients m_{c} and η_{c} from a slope and an intercept of the cycle deterioration prediction line; and
a step of determining the cycle capacity retention rate from the Weibull coefficients me and ne and the formula (2).

A thirteenth aspect of the present invention resides in the secondary battery state of health estimation apparatus according to the eleventh or twelfth aspect,
the apparatus executing
a step of determining the state of health from four arithmetic operations on the float capacity retention rate and the cycle capacity retention rate.

A fourteenth aspect of the present invention resides in the secondary battery state of health estimation apparatus according to any one of the eleventh to thirteenth aspects,
the apparatus executing
a step of estimating the state of health as the state of health in the period t or at the cycle number N from the following formula (A):

$$[ Equation 11 ]$$

$$State of health ( SOH ) = exp \{ - {( \frac{t}{{η}_{f}} )}^{{m}_{f}} \} \times exp \{ - {( \frac{N}{{η}_{c}} )}^{{m}_{c}} \} \qquad ( A )$$

A fifteenth aspect of the present invention resides in the secondary battery state of health estimation apparatus according to any one of the eleventh to thirteenth aspects,
the apparatus executing
a step of estimating the state of health as the state of health in the period t or at the cycle number N from the following formula (B):

$$[ Equation 12 ]$$

$$State of health ( SOH ) = exp \{ - {( \frac{t}{{η}_{f}} )}^{{m}_{f}} \} + exp \{ - {( \frac{N}{{η}_{c}} )}^{{m}_{c}} \} \qquad ( B )$$

### Effects of the Invention

According to the present invention, there can be provided a secondary battery state of health estimation method, a secondary battery state of health estimation program, and a secondary battery state of health estimation apparatus, which separately calculate a float capacity retention rate ascribed to deterioration dependent on an elapsed time, and a cycle capacity retention rate ascribed to deterioration dependent on the number of charges/discharges, thereby estimating the state of health of a secondary battery accurately for a long period of time.

### BRIEF DESCRIPTION OF THE DRAWINGS

FIG. 1 is a view showing the schematic configuration of a storage battery system, as an example of a secondary battery, to which the method of the present invention is applied.

FIG. 2 is a functional block diagram showing an example of the schematic configuration of a control unit in FIG. 1.

FIG. 3 is a schematic flow diagram of the method of the present invention.

FIG. 4 is a view showing an example of a Weibull plot of the results of a float test.

FIG. 5 is a view showing an example of a Weibull plot of the results of a cycle test.

FIG. 6 is a view showing the results of Example 1.

FIGS. 7(a) to 7(c) are views showing the results of Example 1.

FIG. 8 is a view showing the results of Example 2.

FIGS. 9(a) to 9(c) are views showing the results of Example 2.

FIG. 10 is a view showing the results of Example 3.

FIGS. 11(a) to 11(c) are views showing the results of Example 3.

FIG. 12 is a view showing the results of Example 4.

FIGS. 13(a) to 13(c) are views showing the results of Example 4.

FIG. 14 is a view showing the results of Example 5.

FIGS. 15(a) to 15(c) are views showing the results of Example 5.

FIG. 16 is a view showing the results of Example 6.

FIGS. 17(a) to 17(c) are views showing the results of Example 6.

FIG. 18 is a view showing the results of Example 7.

FIGS. 19(a) to 19(c) are views showing the results of Example 7.

FIG. 20 is a view showing the results of Example 8.

FIGS. 21(a) to 21(c) are views showing the results of Example 8.

### MODE FOR CARRYING OUT THE INVENTION

The present invention will be described in detail below based on its embodiments.

### Embodiment 1

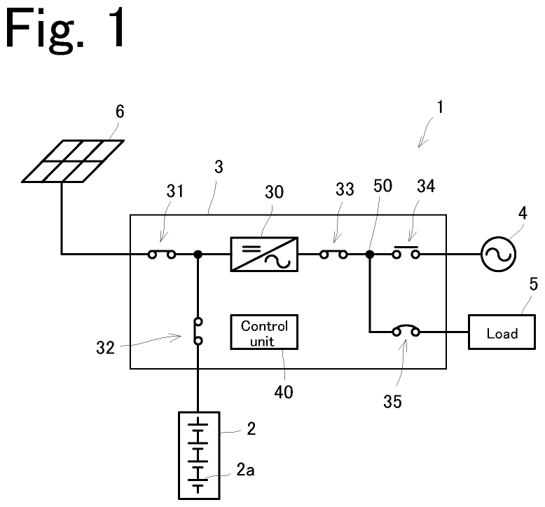

FIG. 1 is a view showing an example of the schematic configuration of a storage battery system, a subject for which the method of the present invention is carried out. As shown in FIG. 1, a storage battery system 1 is equipped with a storage battery 2, which is a secondary battery storing electric power (or power), and a power regulator 3. To the power regulator 3 are connected a commercial power source 4, a load 5, and further a solar power generation device 6 as a generator for generating power, for example, using natural energy.

The storage battery 2 is configured to be capable of charging and discharging power, and is constituted by a single or a plurality of rechargeable and dischargeable secondary battery cell(s) 2a. As the secondary battery cell 2a constituting the storage battery 2, a lithium ion battery, a nickel-metal hydride battery, a nickel-cadmium battery, or a lead-acid battery, for example, can be used. In the present embodiment, a lithium ion battery is used as the storage battery 2. The plurality of secondary battery cells 2a are connected based on functions and capabilities required of a storage battery, and may be connected in series or in parallel.

The power regulator 3 is a so-called power conditioner, and has an inverter 30 for rectifying alternating current power supplied from the commercial power source 4, and converting direct current power from the storage battery 2 or the solar power generation device 6 into alternating current power and outputting it to the load 5; a plurality of switches (first switch 31 to fifth switch 35); and a control unit 30 for exercising overall control over the power regulator 3. In the present embodiment, the inverter 30 serves as a bidirectional inverter having the function of converting the inputted direct current power to alternating current power and outputting it, and the function of converting the inputted alternating current power to direct current power and outputting it.

The commercial power source 4 is supplied with power from an electricity provider and, in the present embodiment, is supplied with alternating current power.

A power generator is a device for generating power by using natural energy (renewable energy) such as sunlight, solar heat, water power, wind power, geothermal heat, wave power, temperature difference, or biomass. In the present embodiment, the solar power generation device 6 is used as the power generator.

The power regulator 3 of the storage battery system 1 mentioned above has the control unit 40 exercise such control as to convert direct current power, which has been generated by the solar power generation device 6, to alternating current via the storage battery 2 and the inverter 30 and supply it to the load 5 at a desired timing in a desired proportion. The power regulator 3 also has the control unit 40 exercise such control as to convert alternating current power, which has been supplied from the commercial power source 4, to direct current via the load 5 and the inverter 30 and supply it to the storage battery 2 at a desired timing.

Furthermore, the power regulator 3 is provided with the plurality of switches (the first switch 31 to the fifth switch 35) which are switching devices openable and closable under the control of the control unit 40. Concretely, the power regulator 3 includes the first switch 31 provided between the solar power generation device 6 and the inverter 30, the second switch 32 provided between the inverter 30 and the storage battery 2, the third switch 33 provided between a junction 50 of the commercial power source 4 and the load 5 and the inverter 30, the fourth switch 34 provided between the junction 50 and the commercial power source 4, and the fifth switch 35 provided between the junction 50 and the load 5. The control unit 40 controls the opening and closing of the first switch 31 to the fifth switch 35 to perform charging to and discharging from the storage battery 2, control over the receiver from the commercial power source 4, and so on. That is, the first switch 31 to the fifth switch 35 can be controlled by the control unit 40. As the fifth switch 35, there may be one which uses a molded case circuit breaker (breaker) without control by the control unit 40.

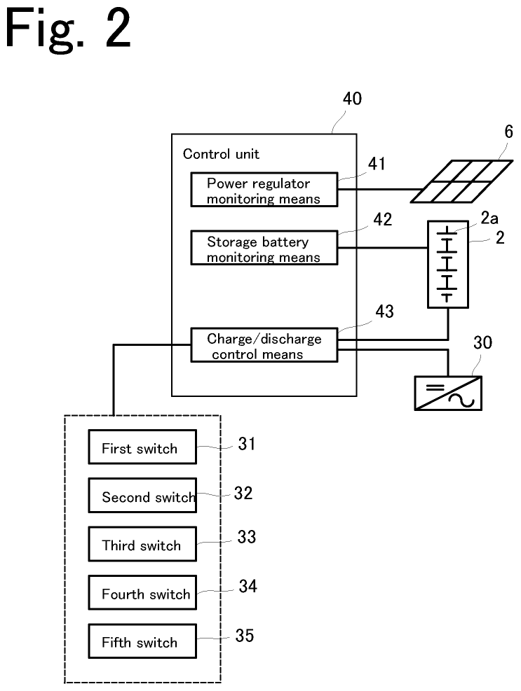

Here, the control unit 40 of the power regulator 3 will be described further by reference to FIG. 2. FIG. 2 is a functional block diagram showing the schematic configuration of the control unit 40.

As shown in FIG. 2, the control unit 40 controls the whole of the power regulator 3, and is equipped with a power generator monitoring means 41, a storage battery monitoring means 42, and a charge/discharge control means 43.

The power generator monitoring means 41 detects the power generation status of the solar power generation device 6. That is, the power generator monitoring means 41 detects whether or not the solar power generation device 6 is in a state of power generation by sunlight. The power generator monitoring means 41 may also detect the amount of power generation in the power generation state of the solar power generation device 6.

The storage battery monitoring means 42 measures the charge/discharge current, the voltage, the ambient temperature or battery temperature, the operating time, the cycle number, etc. of the storage battery 2, to estimate its SOC (State of Charge), SOH, etc. Moreover, the storage battery monitoring means 42 of the present embodiment functions as a monitor for monitoring the voltage, current, temperature, etc. of each secondary battery cell 2a or each battery cell group composed of the plurality of secondary battery cells 2a (i.e., CMU: Cell Monitor Unit). The storage battery monitoring means 42 senses an abnormality in the voltage, current, temperature, etc. of the secondary battery cell 2a or the group of the plurality of secondary battery cells 2a, and communicates the occurrence of the abnormality to the charge/discharge control means 43.

The charge/discharge control means 43 controls the inverter 30 and the first switch 31 to the fifth switch 35 based on various conditions, thereby controlling the charging/discharging of the storage battery 2 and the power supply from the commercial power source 4.

The power generator monitoring means 41, the storage battery monitoring means 42, and the charge/discharge control means 43 described above can be realized by a central processor (CPU: Central Processing Unit) constituting the power regulator 3, a memory capable of reading and writing (RAM: Random Access Memory), which is an example of storage means, and a memory dedicated to reading (ROM: Read Only Memory) for storing various programs, although not shown.

The method of the present invention is applied, with the aforementioned storage battery system being targeted. It goes without saying, however, that the target intended is not limited to such a storage battery system.

The method of the present invention is intended for a secondary battery in actual use, and estimates the state of health of the secondary battery. That is, the method acquires data, such as the temperature, current, voltage, operating time, and cycle number of the secondary battery in operation, and estimates the state of health (SOH) based on the data.

The above method of the present invention may be performed by the storage battery monitoring means 42. However, the data gathered by the storage battery monitoring means 42 may be transmitted to an external arithmetic unit, and the method of the present invention may be performed by the arithmetic unit acquiring the data.

A secondary battery state of health estimation apparatus, which performs the above method of the present invention, is equipped with, for example, a storage means storing data on at least one of a cycle test and a float test, a data acquisition means for acquiring data on the secondary battery in operation, a period t, and a cycle number N from the secondary battery, and an arithmetic unit for performing various arithmetic operations.

The storage means, the data acquisition means, and the arithmetic unit are preferably those of a server to be connected via a network such as the Internet, but may be computers connected to a network.

In the present invention, the terminology is used as defined below.

The state of health (SOH) of a secondary battery is considered by distinguishing between a float capacity retention rate ascribed to deterioration due to the use of the secondary battery, and a cycle capacity retention rate ascribed to deterioration due to charges/discharges. The float capacity retention rate to be estimated is designated as the capacity retention rate based on the measurement values of a float test. The cycle capacity retention rate to be estimated is designated as the capacity retention rate based on the measurement values of a cycle test.

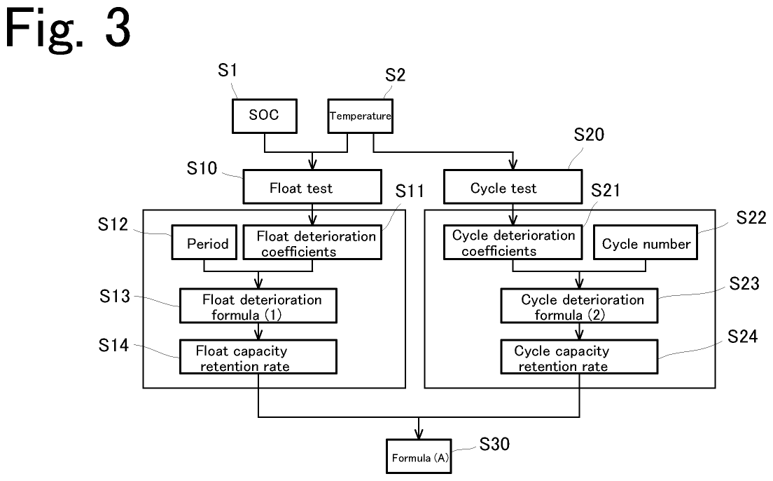

A schematic flow diagram of an example of the method of the present invention will be shown in FIG. 3.

In the present invention, the estimation of the state of health (SOH) of the secondary battery is made by separately estimating the float capacity retention rate obtained from the float test and the cycle capacity retention rate obtained from the cycle test.

According to the method of the present invention, the following tests are conducted for a secondary battery of a predetermined type: In a float test (S10), the secondary battery is operated, and changes in the capacity during the operating time are measured at each SOC (S1) and at each temperature (S2). In a cycle test (S20), SOC is increased and decreased repeatedly, with the period of charging from SOC of 0% until SOC of 100% and discharging from SOC of 100% until SOC of 0% being counted as one cycle, and the duration of the cycle being constant. The cycle test is conducted at a predetermined temperature (S2).

In estimating the float capacity retention rate, float deterioration coefficients (S11) obtained from the measurement values of the float test and period (S12) are introduced into a float deterioration formula (1) (S13) to determine the float capacity retention rate (S14).

In estimating the cycle capacity retention rate, on the other hand, cycle deterioration coefficients (S21) obtained from the measurement values of the cycle test and a cycle number (S22) are introduced into a cycle deterioration formula (2) (S23) to determine the cycle capacity retention rate (S24).

With the present invention, an estimation formula (A) for the state of health (SOH) shown below is used (Step S30) to estimate the state of health (SOH (t)) of a battery cell or the like as a subject.

In the above-mentioned storage battery system, the storage battery monitoring means 42 acquires the temperature, current, voltage, operating time, etc. of each secondary battery cell 2a or each battery cell group composed of the plurality of secondary battery cells 2a and, by use of these parameters, estimates the state of health of the subject battery cell or the like from the estimation formula (A) for the state of health (SOH) indicated below.

In utilizing the estimation formula (A) for the state of health, it is preferred to obtain Weibull coefficients m_{f}, η_{f}, m_{c} and η_{c} beforehand by the float test and the cycle test using a test battery cell of the same type as the subject battery cell.

Since the Weibull coefficients m_{f}, η_{f}, m_{c} and η_{c} are dependent on the capacity, structure, material, etc. of a battery cell, they differ according to the type of the battery cell. It is preferred, therefore, to use a test battery cell of the same type. If the same type of test battery cell is not used, the results of estimation of the state of health deviate from those of the storage battery system. Even the test battery cell of the same type gives results different according to an average charge rate (average SOC) representing its status of use. Thus, it is necessary to obtain the Weibull coefficients m_{f}, η_{f}, m_{c}, and η_{c} beforehand for each average SOC. Moreover, the Weibull coefficients m_{f}, η_{f}, m_{c}, and η_{c} also vary with the operating temperature, so that they should preferably be determined for each temperature.

From the temperature, current and voltage of the battery cell or the like acquired by the storage battery monitoring means 42, the average SOC of the battery in operation is determined. Weibull coefficients m_{f}, η_{f}, m_{c}, η_{c} corresponding to the determined average SOC and the temperature are selected, and the state of health (SOH in the period t or at the cycle number N is estimated from the float capacity retention rate and the cycle capacity retention rate of the secondary battery.

$$[ Equation 13 ]$$

$$Float capacity retention rate = exp \{ - {( \frac{t}{{η}_{f}} )}^{{m}_{f}} \} \qquad ( 1 )$$

$$Cycle capacity retention rate = exp \{ - {( \frac{N}{{η}_{c}} )}^{{m}_{c}} \} \qquad ( 2 )$$

A secondary battery state of health estimation method using the above-described estimation formula (A) for the state of health will be described in detail below.

The method of the present invention is predicated on a secondary battery state of health estimation method which estimates the state of health of a secondary battery based on the Weibull law by grasping the secondary battery as an assembly of partial batteries, and predicting the failure rate of the partial batteries. However, the inventive method is characterized in that the state of health of the secondary battery is estimated by estimating the float capacity retention rate from the float test and the cycle capacity retention rate from the cycle test distinctively, and estimating the state of health in the period t or at the cycle number N from the float capacity retention rate and the cycle capacity retention rate of the secondary battery. By estimating the float capacity retention rate and the cycle capacity retention rate separately, a more accurate state of health can be estimated, and the state of health after long-term use, in particular, can be estimated more accurately, as will be described in more detail later. As noted here, the effects of the present invention are great in judging the life of the secondary battery.

The float capacity retention rate is the capacity retention rate based on the measurements of the float test, and refers to deterioration dependent on the use period of the secondary battery, while the cycle capacity retention rate is the capacity retention rate based on the measurements of the cycle test, and refers to deterioration dependent on a cycle number, with charge and discharge constituting one cycle.

Here, the method of estimating the state of health in the period t or at the cycle number N from the float capacity retention rate and the cycle capacity retention rate of the secondary battery is not limited, and an estimation method may be defined, as appropriate, according to an object intended. By making the estimation using the float capacity retention rate and the cycle capacity retention rate, however, the capacity retention rate after long-term use, in particular, can be estimated more accurately. Thus, the effects of the present invention are great in judging the life of the secondary battery.

The method of estimating the state of health in the period t or at the cycle number from N the float capacity retention rate and the cycle capacity retention rate of the secondary battery can be concretely exemplified by a method which determines it from four arithmetic operations on the float capacity retention rate and the cycle capacity retention rate.

Which of the four arithmetic operations on the float capacity retention rate and the cycle capacity retention rate should be used can be selected, as appropriate, by the system for estimation, but it is preferred to use the formula (A) or formula (B) indicated below.

That is, the state of health is preferably estimated as the state of health in the period t or at the cycle number N from the following formula (A) or formula (B):

The formula (A) is preferably used if there is a strong correlation between cycle deterioration and float deterioration. In other case, the use of the formula (B) is preferred.

$$[ Equation 14 ]$$

$$State of health ( SOH ) = exp \{ - {( \frac{t}{{η}_{f}} )}^{{m}_{f}} \} \times exp \{ - {( \frac{N}{{η}_{c}} )}^{{m}_{c}} \} \qquad ( A )$$

$$State of health ( SOH ) = exp \{ - {( \frac{t}{{η}_{f}} )}^{{m}_{f}} \} + exp \{ - {( \frac{N}{{η}_{c}} )}^{{m}_{c}} \} \qquad ( B )$$

A procedure for determining Weibull coefficients will be explained below.

### (Float Test for Coefficient Determination)

In regard to a secondary battery of a predetermined type, the secondary battery is operated at a predetermined temperature, the operation is fixed at predetermined SOC, and changes in the capacity during the operating time are measured. If necessary, the test is conducted similarly, with the state of a different operating temperature or different SOC being adopted. For example, the test is conducted for confirming capacity, with the voltage being fixed at SOC of 50%, and the test sample being left standing at each different temperature such as 25° C., 45° C. or 60° C. Also, the test is conducted for confirming capacity, with SOC being fixed at a voltage having a different percentage, and the temperature being each of 25° C., 45° C. and 60° C.

### (Cycle Test for Coefficient Determination)

For a secondary battery of a predetermined type, SOC is increased and decreased repeatedly, with the period of charging from SOC of 0% until SOC of 100% and discharging from SOC of 100% until SOC of 0% being counted as one cycle, and the duration of the cycle being constant. For example, if charges and discharges are performed, with the number of charges and discharges being set at 3/day, 3 cycles can be carried out in a day, 300 cycles in 100 days, and 3,000 cycles in 1,000 days.

Capacity corresponding to the period of time corresponding to the cycle number is measured, and the total cycle test capacity retention rate for determining Weibull coefficients is acquired.

The acquired measurement value is the capacity for each cycle number obtained when the secondary battery is operated at the predetermined temperature. It suffices that the number of cycles and the measurement value are in correspondence. The measurement may be made in each cycle, may be made at a predetermined number, or may be made irregularly. For a more accurate estimation of SOH, as many measurement values as possible are preferred.

The state of health is a value obtained by dividing the capacity after deterioration by the capacity at the beginning of the test, and is the proportion of the capacity after deterioration to the initial capacity retention rate. That is, the total cycle test capacity retention rate is a value obtained by dividing the measurement value, which has been acquired by the cycle test, by the initial full charge capacity.

(Method of Actual Value Measurement for Coefficient Determination from Secondary Battery in Operation)

The actual measurement value for coefficient determination may be directly obtained from the secondary battery as the subject for estimation of the state of health (SOH), for example, from the aforementioned storage battery system. In regard to a predetermined operating period from the start of operation, the capacity is measured when predetermined SOC is reached, whereby a measured value for float coefficient determination can be acquired. When a predetermined cycle number is reached from the start of operation, the capacity is measured, whereby a measured value for cycle coefficient determination can be acquired. How to count the cycle number for acquisition of the measured value for cycle coefficient determination can be decided as appropriate. For example, a set of charges and discharges by which the capacity changes by 50% or more of the full charge capacity may be counted as one cycle; whenever a specific SOC percentage is passed twice, one cycle may be counted; or in case the integrated actual charge/discharge capacity coincides with the capacity in one cycle of charge and discharge of the battery, one cycle may be counted. The battery temperature does not vary greatly depending on an environment where the storage battery system is disposed, so that the battery temperature can be measured, and the average temperature can be used.

The state of health is a value obtained by dividing the capacity after deterioration by the capacity at the beginning of the test, and is the proportion of the capacity after deterioration to the initial capacity retention rate. That is, the state of health is a value obtained by dividing the measurement value, which has been acquired from the storage battery system, by the initial full charge capacity.

The state of health of the storage battery system can be estimated if predetermined Weibull coefficients are determined by the following procedure:

(Method for Determining Deterioration Coefficients m_{f}, η_{f} from Measurement Values of Float Test)

The state of health obtained from the float test is taken as a measured float capacity retention rate, and this float capacity retention rate is Weibull plotted in relation to In(period) and In(In(1/capacity retention rate)) to prepare a Weibull plot of the float capacity retention rate. A float deterioration prediction line, represented by a straight-line equation, is estimated from the Weibull plot of the float capacity retention rate. The Weibull coefficients m_{f} and η_{f} are obtained from the slope and intercept of the float deterioration prediction line.

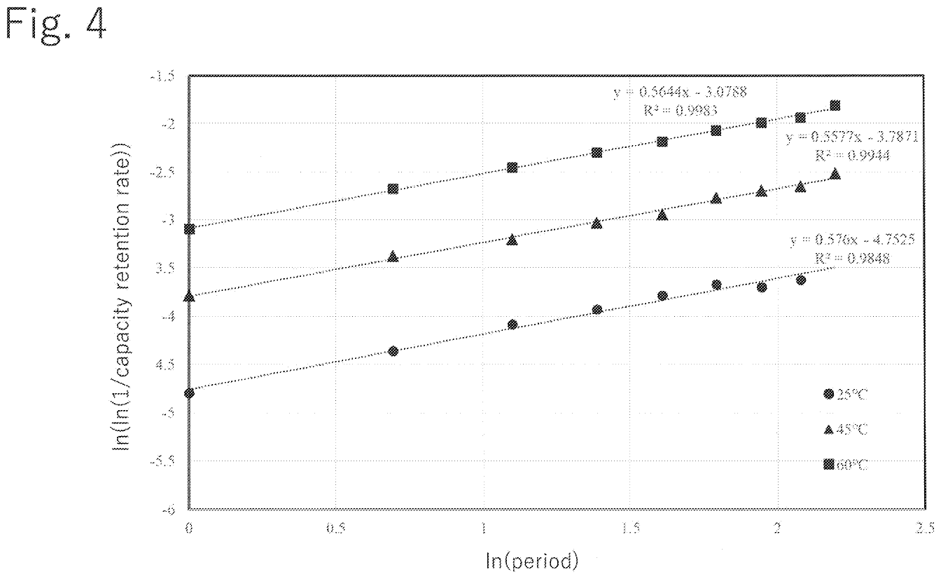

FIG. 4 is an example of Weibull plotting the results of the float test as described above. It shows the plot of the actual values measured at 25° C. and SOC of 50%, 45° C. and SOC of 50%, and 60° C. and SOC of 50%. Under the respective conditions, the Weibull coefficients m_{f}, η_{f} can be determined. From them, the float capacity retention rate can be determined.

(Method for Determining Deterioration Coefficients m_{c}, η_{c} from Measurement Values of Cycle Test)

The capacity retention rate obtained from the cycle test is taken as a measured cycle capacity retention rate, and this cycle capacity retention rate is Weibull plotted in relation to In(cycle number) and In(In(1/capacity retention rate)) to prepare a Weibull plot of the cycle capacity retention rate. A cycle deterioration prediction line, represented by a straight-line equation, is estimated from the Weibull plot of the cycle capacity retention rate. The Weibull coefficients m_{c} and η_{c} are obtained from the slope and intercept of the cycle deterioration prediction line.

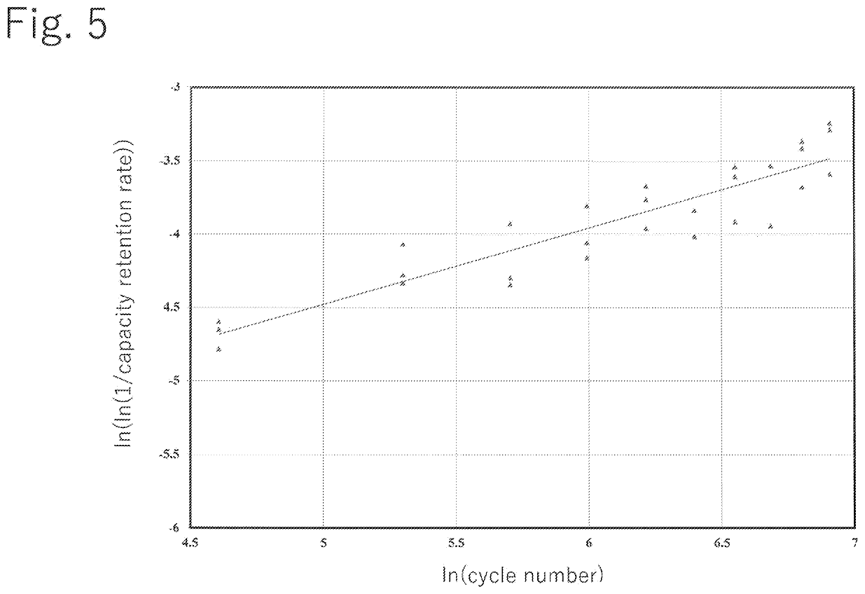

FIG. 5 is an example of Weibull plotting the results of the cycle test as described above. Under the measurement conditions, the Weibull coefficients m_{c}, η_{c} can be determined. From them, the cycle capacity retention rate can be determined.

### (Estimation of State of Health)

In regard to a secondary battery of the same type as the type of the subject for estimation, Weibull coefficients m_{f}, η_{f}, m_{c}, and η_{c} corresponding to a predetermined temperature and predetermined SOC are selected. They are introduced into the aforementioned estimation formula (A) to estimate the state of health (SOH) during the period t.

By estimating a future state of health (SOH) more accurately, parameters for charge/discharge of a secondary battery used for a long period until being deteriorated can be properly set. Thus, the battery can be prevented from overcharge and overdischarge, and can be used more safely. Also, the remaining power of the storage battery system can be detected, and the timings of maintenance, replacement of the battery, etc. can be grasped more accurately.

### EXAMPLES

### Example 1

Secondary battery (PD50S03): Composed of lithium iron phosphate as a positive electrode, graphite as a negative electrode, and ethylene carbonate (EC):dimethyl carbonate (DMC)=3:7 as an electrolyte solution with 1.2 M of lithium hexafluorophosphate (LiPF₆) being inserted as a supporting electrolyte. The positive electrode and the negative electrode were laminated elements, and disposed face-to-face, with a polyolefin separator interposed therebetween. Had a capacity of 50 Ah. The elements were housed in an SUS metal case.

A float test and a cycle test were conducted using this secondary battery.

The float test was conducted at each of various SOCs and temperatures.

The cycle test was conducted at each of various SOCs and temperatures using six cycles per day.

Using a system (battery capacity 2.5 kWh) composed of 16 secondary batteries of the same type which were connected in series, data were acquired to find the average SOC of 92.1%. The average temperature was 28.2° C.

The Weibull coefficient m_{f} from the float test, corresponding to the average SOC and the average temperature, was 0.270603, and the corresponding Weibull coefficient η_{f} was 9.341202.

The Weibull coefficient m_{c} from the cycle test was 0.659873, and the corresponding Weibull coefficient η_{c} was 10.65732.

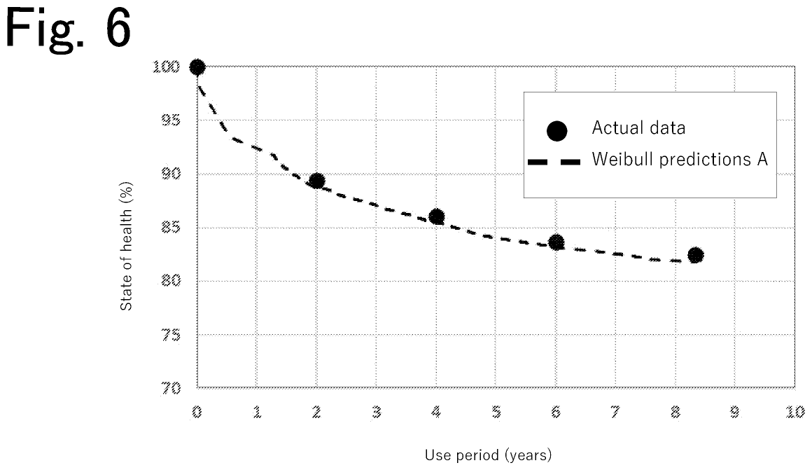

The results of estimation of the state of health from the formulas (1), (2) and (A) using these Weibull coefficients are shown in FIG. 6 as Weibull predictions A. FIG. 6 shows the actual data along with the predicted values. The predicted values were confirmed to be nearly coincident with the actual data.

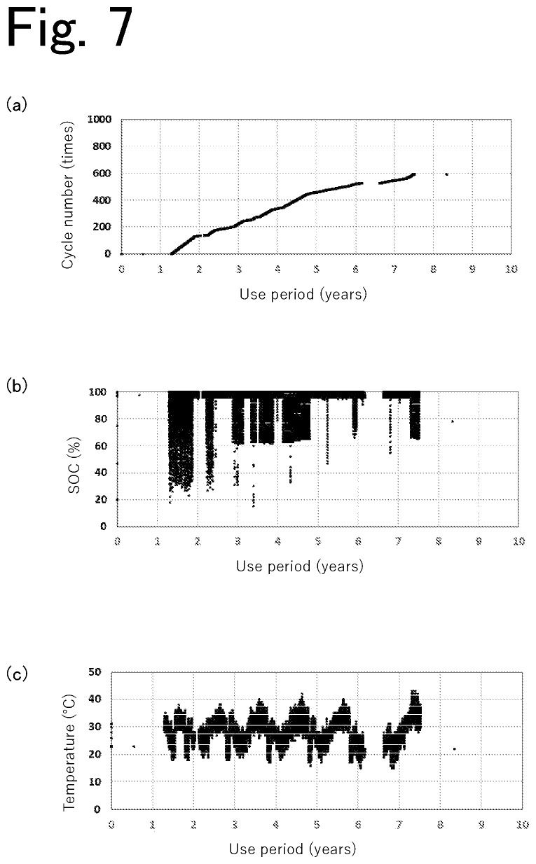

FIG. 7(a) shows changes in the cycle number of the actual machine, FIG. 7(b) shows changes in the SOC of the actual machine, and FIG. 7(c) shows changes in the temperature of the actual machine.

### Example 2

A float test and a cycle test were conducted using a secondary battery of the same type as that in Example 1.

The float test was conducted at each of various SOCs and temperatures.

The cycle test was conducted at each of various SOCs and temperatures using six cycles per day.

Using a system (battery capacity 2.5 kWh) composed of 16 of the secondary batteries of the same type which were connected in series, data were acquired to find the average SOC of 97.0%. The average temperature was 27.8° C.

The Weibull coefficient m_{f} from the float test, corresponding to the average SOC and the average temperature, was 0.962004, and the corresponding Weibull coefficient η_{f} was 4.269083.

The Weibull coefficient me from the cycle test was 0.04926, and the corresponding Weibull coefficient η_{c} was 57.4858.

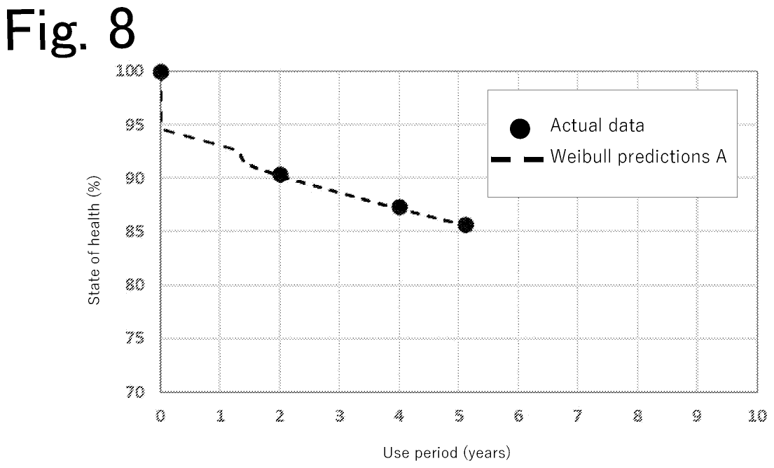

Using these Weibull coefficients, the state of health was estimated from the formulas (1), (2) and (A). The results are shown in FIG. 8 as Weibull predictions A. FIG. 8 shows the actual data along with the predicted values. The predicted values were confirmed to be almost coincident with the actual data.

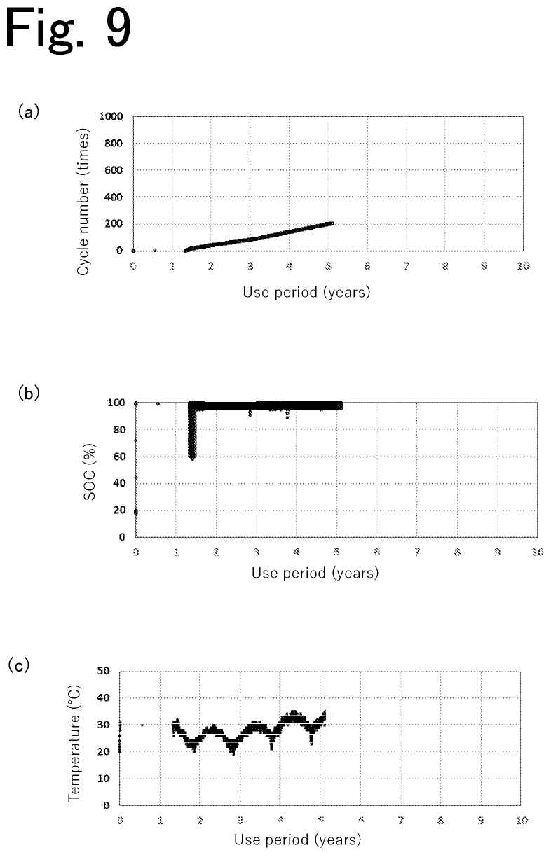

FIG. 9(a) shows changes in the cycle number of the actual machine, FIG. 9(b) shows changes in the SOC of the actual machine, and FIG. 9(c) shows changes in the temperature of the actual machine.

### Example 3

A float test and a cycle test were conducted using a secondary battery of the same type as that in Example 1.

The float test was conducted at each of various SOCs and temperatures.

The cycle test was conducted at each of various SOCs and temperatures using six cycles per day.

Using a system (battery capacity 2.5 kWh) composed of 16 of the secondary batteries of the same type which were connected in series, data were acquired to find the average SOC of 77.9%. The average temperature was 31.5° C.

The Weibull coefficient m_{f} from the float test, corresponding to the average SOC and the average temperature, was 0.355503, and the corresponding Weibull coefficient η_{f} was 7.313371.

The Weibull coefficient me from the results of the cycle test was 0.665076, and the corresponding Weibull coefficient ne was 10.78985.

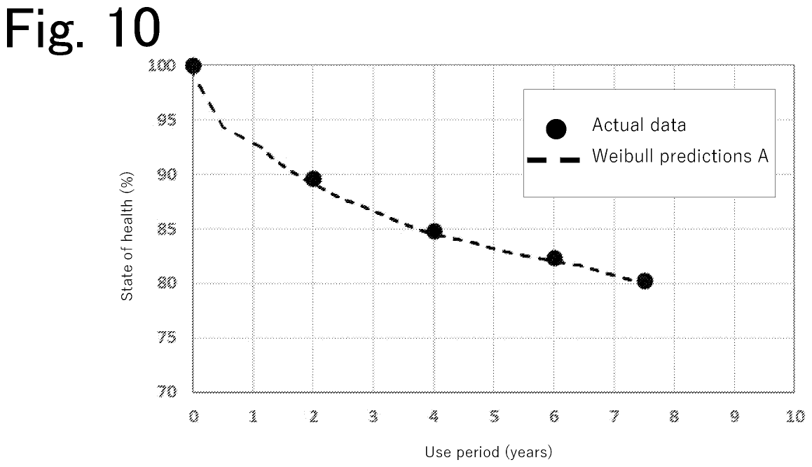

Using these Weibull coefficients, the state of health was estimated from the formulas (1), (2) and (A). The results are shown in FIG. 10 as Weibull predictions A. FIG. 10 shows the actual data along with the predicted values. The predicted values were confirmed to be almost coincident with the actual data.

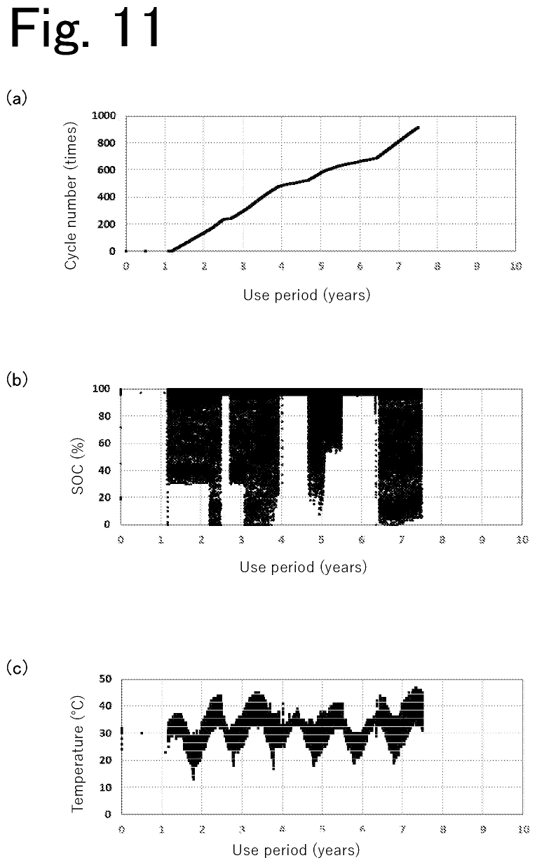

FIG. 11(a) shows changes in the cycle number of the actual machine, FIG. 9(b) shows changes in the SOC of the actual machine, and FIG. 9(c) shows changes in the temperature of the actual machine.

### Example 4

A float test and a cycle test were conducted using a secondary battery of the same type as that in Example 1.

The float test was conducted at each of various SOCs and temperatures.

The cycle test was conducted at each of various SOCs and temperatures using six cycles per day.

Using a system (battery capacity 2.5 kWh) composed of 16 of the secondary batteries of the same type which were connected in series, data were acquired to find the average SOC of 96.7%. The average temperature was 30.5° C.

The Weibull coefficient m_{f} from the float test, corresponding to the average SOC and the average temperature, was 0.507544, and the corresponding Weibull coefficient η_{f} was 5.396954.

The Weibull coefficient me from the cycle test was 0.105096, and the corresponding Weibull coefficient η_{c} was 44.51101.

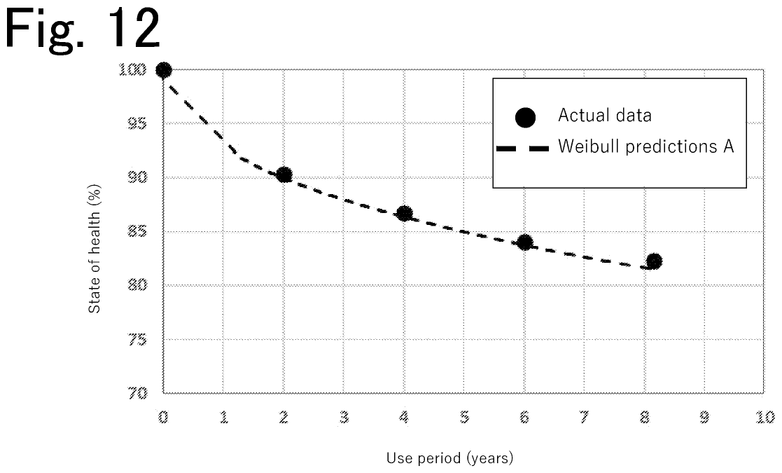

Using these Weibull coefficients, the state of health was estimated from the formulas (1), (2) and (A). The results are shown in FIG. 12 as Weibull predictions A. FIG. 12 shows the actual data along with the predicted values. The predicted values were confirmed to be almost coincident with the actual data.

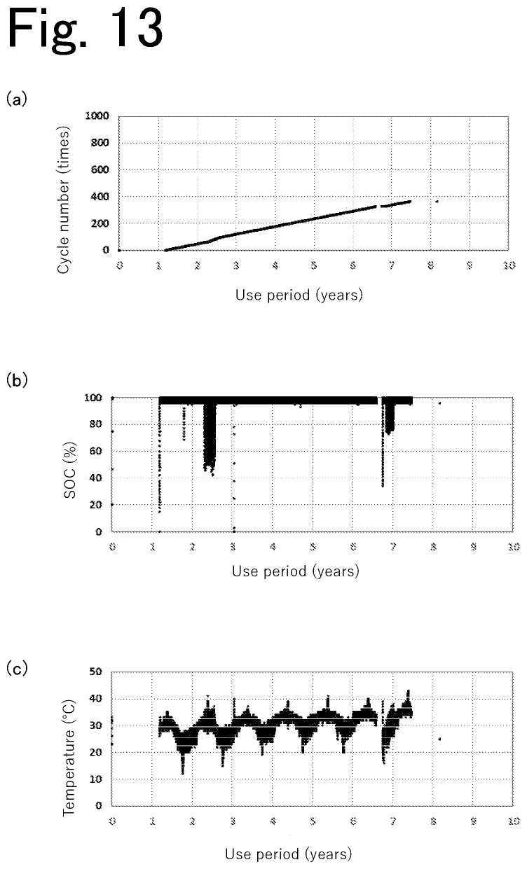

FIG. 13(a) shows changes in the cycle number of the actual machine, FIG. 13(b) shows changes in the SOC of the actual machine, and FIG. 13(c) shows changes in the temperature of the actual machine.

### Example 5

A float test and a cycle test were conducted using a secondary battery of the same type as that in Example 1.

The float test was conducted at each of various SOCs and temperatures.

The cycle test was conducted at each of various SOCs and temperatures using six cycles per day.

Using a system (battery capacity 2.5 kWh) composed of 16 of the secondary batteries of the same type which were connected in series, data were acquired to find the average SOC of 92.1%. The average temperature was 28.2° C.

The Weibull coefficient me from the float test, corresponding to the average SOC and the average temperature, was 0.270603, and the corresponding Weibull coefficient η_{f} was 9.341202.

The Weibull coefficient me from the cycle test was 0.659873, and the corresponding Weibull coefficient η_{c} was 10.65732.

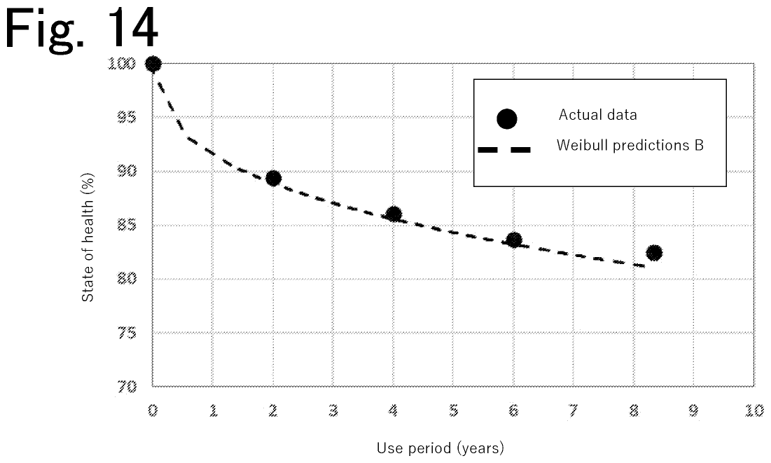

Using these Weibull coefficients, the state of health was estimated from the formulas (1), (2) and (B). The results are shown in FIG. 14 as Weibull predictions B. FIG. 14 shows the actual data along with the predicted values. The predicted values were confirmed to be almost coincident with the actual data.

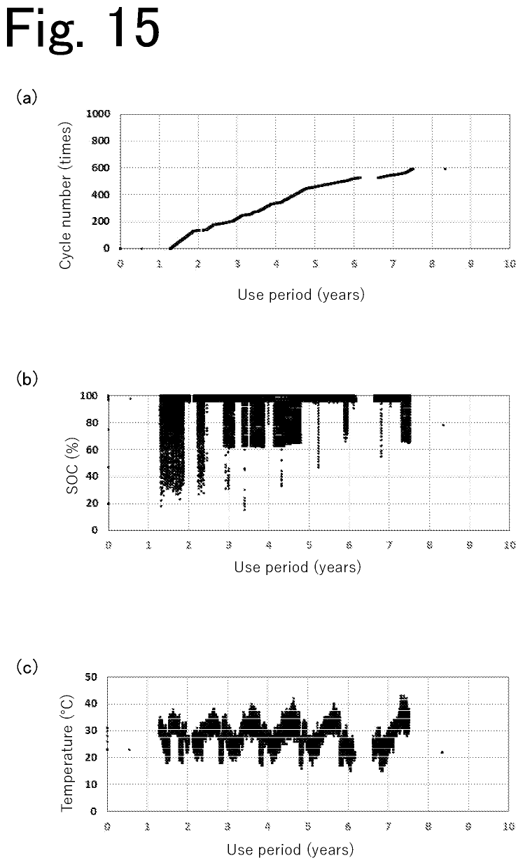

FIG. 15(a) shows changes in the cycle number of the actual machine, FIG. 15(b) shows changes in the SOC of the actual machine, and FIG. 15(c) shows changes in the temperature of the actual machine.

### Example 6

A float test and a cycle test were conducted using a secondary battery of the same type as that in Example 1.

The float test was conducted at each of various SOCs and temperatures.

The cycle test was conducted at each of various SOCs and temperatures using six cycles per day.

Using a system (battery capacity 2.5 kWh) composed of 16 of the secondary batteries of the same type which were connected in series, data were acquired to find the average SOC of 97.0%. The average temperature was 27.8° C.

The Weibull coefficient m_{f} from the float test, corresponding to the average SOC and the average temperature, was 0.962004, and the corresponding Weibull coefficient η_{f} was 4.269083.

The Weibull coefficient m_{c} from the cycle test was 0.04926, and the corresponding Weibull coefficient η_{c} was 57.4858.

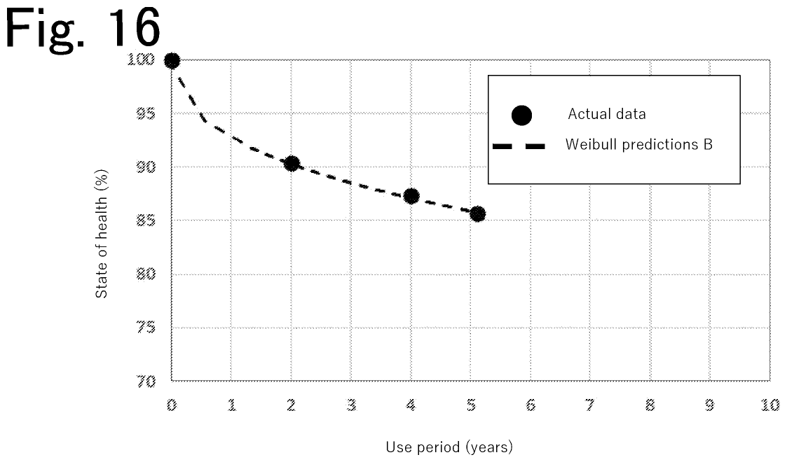

Using these Weibull coefficients, the state of health was estimated from the formulas (1), (2) and (B). The results are shown in FIG. 16 as Weibull predictions B. FIG. 16 shows the actual data along with the predicted values. The predicted values were confirmed to be almost coincident with the actual data.

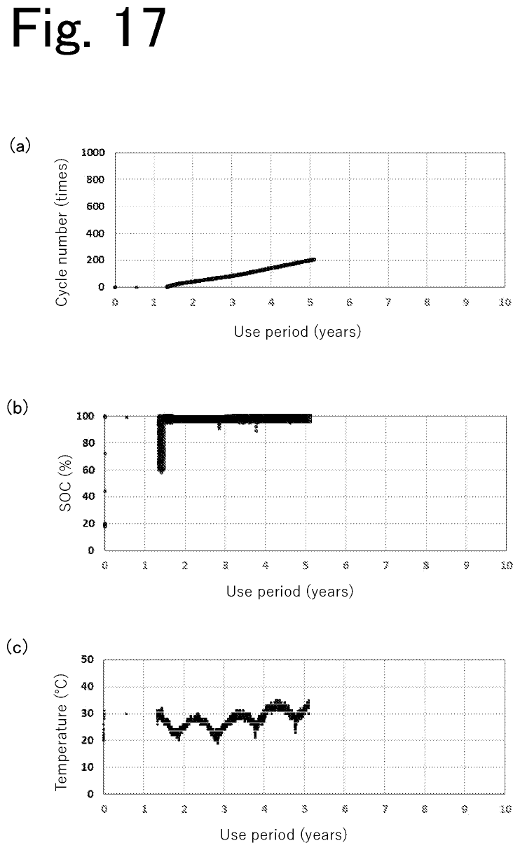

FIG. 17(a) shows changes in the cycle number of the actual machine, FIG. 17(b) shows changes in the SOC of the actual machine, and FIG. 17(c) shows changes in the temperature of the actual machine.

### Example 7

A float test and a cycle test were conducted using a secondary battery of the same type as that in Example 1.

The float test was conducted at each of various SOCs and temperatures.

The cycle test was conducted at each of various SOCs and temperatures using six cycles per day.

Using a system (battery capacity 2.5 kWh) composed of 16 of the secondary batteries of the same type which were connected in series, data were acquired to find the average SOC of 77.9%. The average temperature was 31.5° C.

The Weibull coefficient me from the float test, corresponding to the average SOC and the average temperature, was 0.962004, and the corresponding Weibull coefficient η_{f} was 4.269083.

The Weibull coefficient me from the cycle test was 0.04926, and the corresponding Weibull coefficient η_{c} was 57.4858.

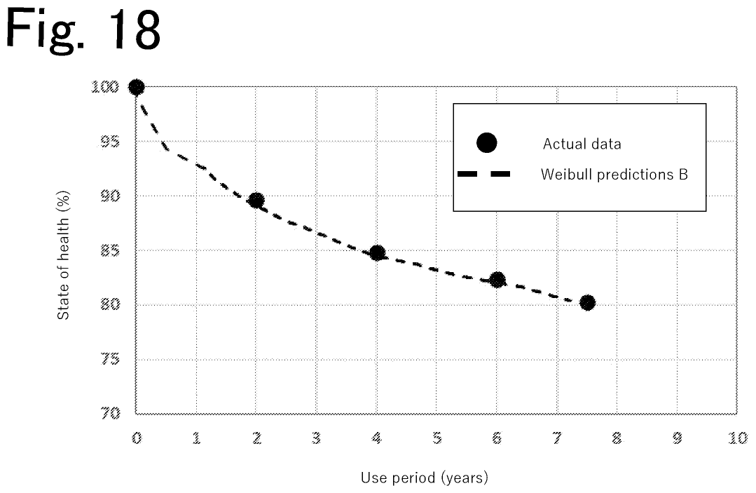

Using these Weibull coefficients, the state of health was estimated from the formulas (1), (2) and (B). The results are shown in FIG. 18 as Weibull predictions B. FIG. 18 shows the actual data along with the predicted values. The predicted values were confirmed to be almost coincident with the actual data.

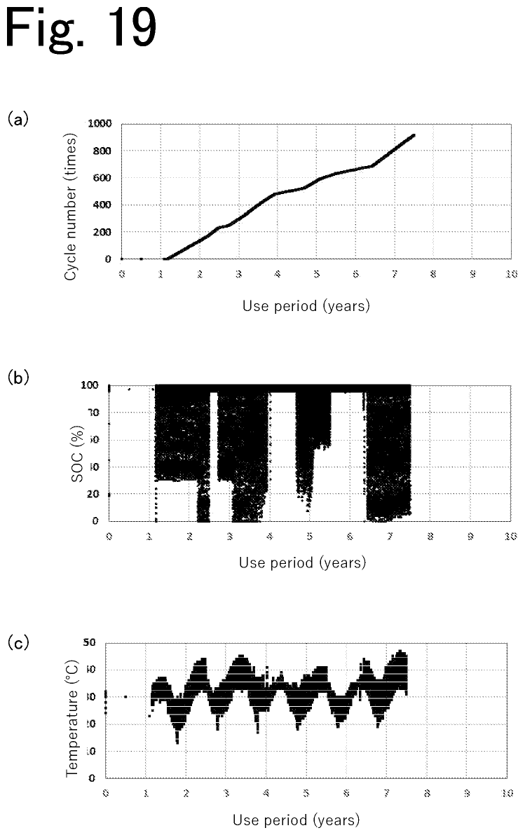

FIG. 19(a) shows changes in the cycle number of the actual machine, FIG. 19(b) shows changes in the SOC of the actual machine, and FIG. 19(c) shows changes in the temperature of the actual machine.

### Example 8

A float test and a cycle test were conducted using a secondary battery of the same type as that in Example 1.

The float test was conducted at each of various SOCs and temperatures.

The cycle test was conducted at each of various SOCs and temperatures using six cycles per day.

Using a system (battery capacity 2.5 kWh) composed of 16 of the secondary batteries of the same type which were connected in series, data were acquired to find the average SOC of 96.7%. The average temperature was 30.5° C.

The Weibull coefficient me from the float test, corresponding to the average SOC and the average temperature, was 0.507544, and the corresponding Weibull coefficient η_{f} was 5.396954.

The Weibull coefficient m_{c} from the cycle test was 0.105096, and the corresponding Weibull coefficient η_{c} was 44.51101.

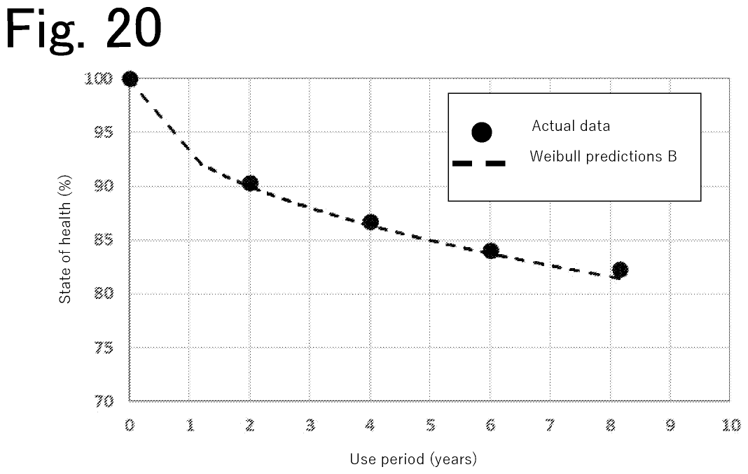

Using these Weibull coefficients, the state of health was estimated from the formulas (1), (2) and (B). The results are shown in FIG. 20 as Weibull predictions B. FIG. 20 shows the actual data along with the predicted values. The predicted values were confirmed to be almost coincident with the actual data.

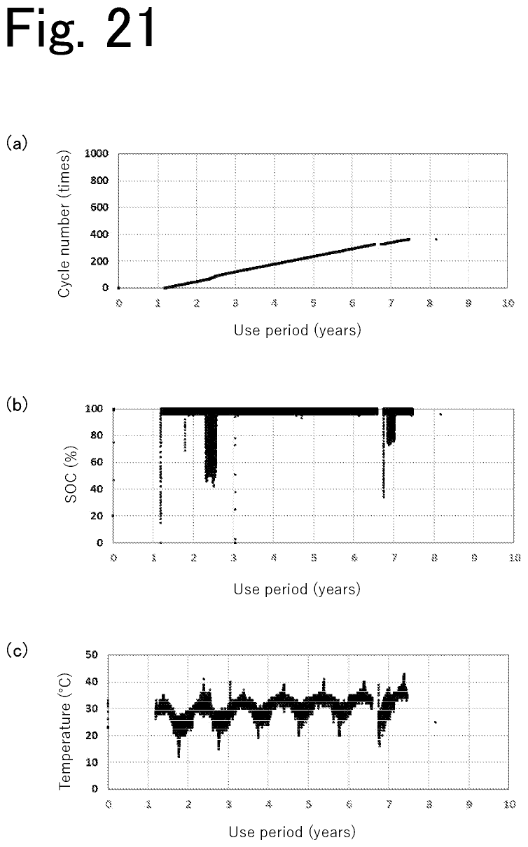

FIG. 21(a) shows changes in the cycle number of the actual machine, FIG. 21(b) shows changes in the SOC of the actual machine, and FIG. 21(c) shows changes in the temperature of the actual machine.

### INDUSTRIAL APPLICABILITY

The present invention can be utilized effectively in an industrial field where a storage battery system using a storage battery as a power supply, and in an industrial field where maintenance and operation of such a storage battery system are performed.

### EXPLANATIONS OF LETTERS OR NUMERALS

1 . . . Storage battery system
2 . . . Storage battery
2a . . . Secondary battery cell
3 . . . Power regulator
4 . . . Commercial power source
5 . . . Load
6 . . . Solar power generation device (power generator)
30 . . . Inverter
31 . . . First switch
32 . . . Second switch
33 . . . Third switch
31 . . . Fourth switch
35 . . . Fifth switch
10 . . . Control unit
11 . . . Power generator monitoring means
12 . . . Storage battery monitoring means
13 . . . Charge/discharge control means

1. A secondary battery state of health (SOH) estimation method, which estimates a state of health (SOH) of a secondary battery by use of a Weibull law, comprising:
obtaining Weibull coefficients m_{f}, η_{f} corresponding to a float capacity retention rate, and the float capacity retention rate represented by the following formula (1), from measurement values of a float test for determining the state of health;
obtaining Weibull coefficients m_{c}, η_{c} corresponding to a cycle capacity retention rate, and the cycle capacity retention rate represented by the following formula (2), from measurement values of a cycle test for determining the state of health; and
estimating the State of Health (SOH) in a period t or at a cycle number N from the float capacity retention rate and the cycle capacity retention rate of the secondary battery.
$$[ Equation 1 ]$$
$$Float capacity retention rate = exp \{ - {( \frac{t}{{η}_{f}} )}^{{m}_{f}} \} \qquad ( 1 )$$
$$Cycle capacity retention rate = exp \{ - {( \frac{N}{{η}_{c}} )}^{{m}_{c}} \} . \qquad ( 2 )$$

2. The secondary battery state of health estimation method according to claim 1, comprising:
taking the capacity retention rate obtained from the float test as a measured float capacity retention rate, and Weibull plotting the measured float capacity retention rate in relation to In(period) and In(In(1/capacity retention rate)) to prepare a Weibull plot of the float capacity retention rate;
estimating a float deterioration prediction line, represented by a straight-line equation, from the Weibull plot of the float capacity retention rate;
obtaining the Weibull coefficients m_{f} and η_{f} from a slope and an intercept of the float deterioration prediction line;
determining the float capacity retention rate from the Weibull coefficients m_{f} and η_{f} and the formula (1);
taking the capacity retention rate obtained from the cycle test as a measured cycle capacity retention rate, and Weibull plotting the measured cycle capacity retention rate in relation to In(cycle number) and In(In(1/capacity retention rate)) to prepare a Weibull plot of the cycle capacity retention rate;
estimating a cycle deterioration prediction line, represented by a straight-line equation, from the Weibull plot of the cycle capacity retention rate;
obtaining the Weibull coefficients m_{c} and η_{c} from a slope and an intercept of the cycle deterioration prediction line; and
determining the cycle capacity retention rate from the Weibull coefficients me and ne and the formula (2).

3. The secondary battery state of health estimation method according to claim 1, comprising:
determining the state of health from four arithmetic operations on the float capacity retention rate and the cycle capacity retention rate.

4. The secondary battery state of health estimation method according to claim 1, comprising:
estimating the state of health as the state of health in the period t or at the cycle number N from the following formula (A):
$$[ Equation 2 ]$$
$$State of health ( SOH ) = exp \{ - {( \frac{t}{{η}_{f}} )}^{{m}_{f}} \} \times exp \{ - {( \frac{N}{{η}_{c}} )}^{{m}_{c}} \} . \qquad ( A )$$

5. The secondary battery state of health estimation method according to claim 1, comprising:
estimating the state of health as the state of health in the period t or at the cycle number N from the following formula (B):
$$[ Equation 3 ]$$
$$State of health ( SOH ) = exp \{ - {( \frac{t}{{η}_{f}} )}^{{m}_{f}} \} + exp \{ - {( \frac{N}{{η}_{c}} )}^{{m}_{c}} \} . \qquad ( B )$$

6. A secondary battery state of health estimation program, which estimates a state of health (SOH) of a secondary battery by use of a Weibull law,
the program comprising making a computer work to perform:
a step of obtaining Weibull coefficients m_{f}, η_{f} corresponding to a float capacity retention rate, and the float capacity retention rate represented by the following formula (1), from measurement values of a float test for determining the capacity retention rate;
a step of obtaining Weibull coefficients m_{c}, η_{c} corresponding to a cycle capacity retention rate, and the cycle capacity retention rate represented by the following formula (2), from measurement values of a cycle test for determining the capacity retention rate; and
a step of estimating the state of health in a period t or at a cycle number N from the float capacity retention rate and the cycle capacity retention rate of the secondary battery.
$$[ Equation 4 ]$$
$$Float capacity retention rate = exp \{ - {( \frac{t}{{η}_{f}} )}^{{m}_{f}} \} \qquad ( 1 )$$
$$Cycle capacity retention rate = exp \{ - {( \frac{N}{{η}_{c}} )}^{{m}_{c}} \} . \qquad ( 2 )$$

7. The secondary battery state of health estimation program according to claim 6,
the program comprising making a computer work to perform:
a step of taking the capacity retention rate obtained from the float test as a measured float capacity retention rate, and Weibull plotting the float capacity retention rate in relation to In(period) and In(In(1/capacity retention rate)) to prepare a Weibull plot of the float capacity retention rate;
a step of estimating a float deterioration prediction line, represented by a straight-line equation, from the Weibull plot of the float capacity retention rate;
a step of obtaining the Weibull coefficients m_{f} and η_{f} from a slope and an intercept of the float deterioration prediction line;
a step of determining the float capacity retention rate from the Weibull coefficients m_{f} and η_{f} and the formula (1);
a step of taking the capacity retention rate obtained from the cycle test as a measured cycle capacity retention rate, and Weibull plotting the cycle capacity retention rate in relation to In(cycle number) and In(In(1/capacity retention rate)) to prepare a Weibull plot of the cycle capacity retention rate;
a step of estimating a cycle deterioration prediction line, represented by a straight-line equation, from the Weibull plot of the cycle capacity retention rate;
a step of obtaining the Weibull coefficients m_{c} and η_{c} from a slope and an intercept of the cycle deterioration prediction line; and
a step of determining the cycle capacity retention rate from the Weibull coefficients me and η_{c} and the formula (2).

8. The secondary battery state of health estimation program according to claim 6,
the program comprising making a computer work to perform:
a step of determining the state of health from four arithmetic operations on the float capacity retention rate and the cycle capacity retention rate.

9. The secondary battery state of health estimation program according to claim 6,
the program comprising making a computer work to perform:
a step of estimating the state of health as the state of health in the period t or at the cycle number N from the following formula (A):
$$[ Equation 5 ]$$
$$State of health ( SOH ) = exp \{ - {( \frac{t}{{η}_{f}} )}^{{m}_{f}} \} \times exp \{ - {( \frac{N}{{η}_{c}} )}^{{m}_{c}} \} . \qquad ( A )$$

10. The secondary battery state of health estimation program according to claim 6,
the program comprising making a computer work to perform:
a step of estimating the state of health as the state of health in the period t or at the cycle number N from the following formula (B):
$$[ Equation 6 ]$$
$$State of health ( SOH ) = exp \{ - {( \frac{t}{{η}_{f}} )}^{{m}_{f}} \} + exp \{ - {( \frac{N}{{η}_{c}} )}^{{m}_{c}} \} . \qquad ( B )$$

11. A secondary battery state of health estimation apparatus, which performs a secondary battery state of health estimation method to estimate a state of health (SOH) of a secondary battery,
the apparatus comprising:
storage means storing data on a cycle test and a float test; and
data acquisition means for acquiring data on the secondary battery in operation, a period t, and a cycle number N from the secondary battery;
the apparatus executing
a step of obtaining Weibull coefficients m_{f}, η_{f} corresponding to a float capacity retention rate, and the float capacity retention rate represented by the following formula (1), from measurement values of the float test;
a step of obtaining Weibull coefficients m_{c}, η_{c} corresponding to a cycle capacity retention rate, and the cycle capacity retention rate represented by the following formula (2), from measurement values of the cycle test; and
a step of estimating the state of health in the period t or at the cycle number N from the float capacity retention rate and the cycle capacity retention rate of the secondary battery.
$$[ Equation 7 ]$$
$$Float capacity retention rate = exp \{ - {( \frac{t}{{η}_{f}} )}^{{m}_{f}} \} \qquad ( 1 )$$
$$Cycle capacity retention rate = exp \{ - {( \frac{N}{{η}_{c}} )}^{{m}_{c}} \} . \qquad ( 2 )$$

12. The secondary battery state of health estimation apparatus according to claim 11,
the apparatus executing
a step of taking the capacity retention rate obtained from the float test as a measured float capacity retention rate, and Weibull plotting the float capacity retention rate in relation to In(period) and In(In(1/capacity retention rate)) to prepare a Weibull plot of the float capacity retention rate;
a step of estimating a float deterioration prediction line, represented by a straight-line equation, from the Weibull plot of the float capacity retention rate;
a step of obtaining the Weibull coefficients m_{f} and η_{f} from a slope and an intercept of the float deterioration prediction line;
a step of determining the float capacity retention rate from the Weibull coefficients m_{f} and η_{f} and the formula (1);
a step of taking the capacity retention rate obtained from the cycle test as a measured cycle capacity retention rate, and Weibull plotting the cycle capacity retention rate in relation to In(cycle number) and In(In(1/capacity retention rate)) to prepare a Weibull plot of the cycle capacity retention rate;
a step of estimating a cycle deterioration prediction line, represented by a straight-line equation, from the Weibull plot of the cycle capacity retention rate;
a step of obtaining the Weibull coefficients m_{c} and η_{c} from a slope and an intercept of the cycle deterioration prediction line; and
a step of determining the cycle capacity retention rate from the Weibull coefficients m_{c} and η_{c} and the formula (2).

13. The secondary battery state of health estimation apparatus according to claim 11,
the apparatus executing
a step of determining the state of health from four arithmetic operations on the float capacity retention rate and the cycle capacity retention rate.

14. The secondary battery state of health estimation apparatus according to claim 11,
the apparatus executing
a step of estimating the state of health as the state of health in the period t or at the cycle number N from the following formula (A):
$$[ Equation 8 ]$$
$$State of health ( SOH ) = exp \{ - {( \frac{t}{{η}_{f}} )}^{{m}_{f}} \} \times exp \{ - {( \frac{N}{{η}_{c}} )}^{{m}_{c}} \} . \qquad ( A )$$

15. The secondary battery state of health estimation apparatus according to claim 11,
the apparatus executing
a step of estimating the state of health as the state of health in the period t or at the cycle number N from the following formula (B):
$$[ Equation 9 ]$$
$$State of health ( SOH ) = exp \{ - {( \frac{t}{{η}_{f}} )}^{{m}_{f}} \} + exp \{ - {( \frac{N}{{η}_{c}} )}^{{m}_{c}} \} . \qquad ( B )$$
